(19) United States
(12) Patent Application Publication
(10) Pub. No.: US 2026/0082813 A1
(43) Pub. Date: Mar. 19, 2026

(54) MEMORY DEVICE

(71) Applicant: Kioxia Corporation, Tokyo (JP)

(72) Inventors: Hyung-Woo AHN, Seongnam-si Gyeonggi-do (KR); Takuya SHIMANO, Seoul (KR); Naoki AKIYAMA, Yokkaichi Mie (JP); Hyungjun CHO, Seongnam-si Gyeonggi-do (KR); Kenichi YOSHINO, Seongnam-si Gyeonggi-do (KR)

(73) Assignee: Kioxia Corporation, Tokyo (JP)

(21) Appl. No.: 19/324,416

(22) Filed: Sep. 10, 2025

(30) Foreign Application Priority Data
Sep. 17, 2024 (JP) 2024-160307

(51) Int. Cl. H10N 50/10; G11C 11/16; H10N 50/85

(52) U.S. Cl. CPC H10N 50/10; G11C 11/161; G11C 11/1659; G11C 11/1673; G11C 11/1675; H10N 50/85

(57) ABSTRACT

According to one embodiment, a memory device includes a memory cell including a variable resistance memory element and a switching element. The switching element includes bottom and top electrodes and a switching material layer between the bottom and top electrodes, the top electrode includes first and second layer portions, the first layer portion is between the switching material layer and the second layer portion, the switching material layer is formed of a material containing Si, O and As, the first layer portion is formed of a conductive material containing C, and the second layer portion is formed of a conductive material containing at least one element selected from Ta, Ti, W, Ni, Mo, Cr, V, Zr, Al, Hf, In, Sn, Ru, Zn and Mg.

### CROSS-REFERENCE TO RELATED APPLICATIONS

This application is based upon and claims the benefit of priority from Japanese Patent Application No. 2024-160307, filed Sep. 17, 2024, the entire contents of which are incorporated herein by reference.

### FIELD

Embodiments described herein relate generally to a memory device.

### BACKGROUND

Memory devices in which a plurality of memory cells including variable resistance memory elements and selectors (switching elements) are integrated on a semiconductor substrate are suggested.

### BRIEF DESCRIPTION OF THE DRAWINGS

FIG. 1 is a perspective view schematically showing the configuration of a memory device according to a first embodiment.

FIG. 2 is a cross-sectional view schematically showing the configuration of the memory device according to the first embodiment.

FIG. 3 is a cross-sectional view schematically showing an example of the configuration of a magnetoresistance effect element in the memory device according to the first embodiment.

FIG. 4 is a cross-sectional view schematically showing another example of the configuration of the magnetoresistance effect element in the memory device according to the first embodiment.

FIG. 5 is a diagram schematically showing the current-voltage characteristic of a selector in the memory device according to the first embodiment.

FIG. 6 is a perspective view schematically showing the configuration of a memory device according to a second embodiment.

FIG. 7 is a cross-sectional view schematically showing the configuration of the memory device according to the second embodiment.

### DETAILED DESCRIPTION

In general, according to one embodiment, a memory device includes: a lower wiring line extending in a first direction; an upper wiring line extending in a second direction intersecting the first direction; and a memory cell provided between the lower wiring line and the upper wiring line and including a variable resistance memory element and a switching element stacked in a third direction intersecting the first direction and the second direction, wherein the switching element includes a structure in which a bottom electrode, a top electrode and a switching material layer provided between the bottom electrode and the top electrode are stacked in the third direction, the top electrode includes a first layer portion and a second layer portion stacked in the third direction, and includes a structure in which the first layer portion is provided between the switching material layer and the second layer portion, the switching material layer is formed of a material containing silicon (Si), oxygen (O) and arsenic (As), the first layer portion is formed of a conductive material containing carbon (C), and the second layer portion is formed of a conductive material containing at least one element selected from tantalum (Ta), titanium (Ti), tungsten (W), nickel (Ni), molybdenum (Mo), chromium (Cr), vanadium (V), zirconium (Zr), aluminum (Al), hafnium (Hf), indium (In), tin (Sn), ruthenium (Ru), zinc (Zn) and magnesium (Mg).

Embodiments will be described hereinafter with reference to the accompanying drawings.

### First Embodiment

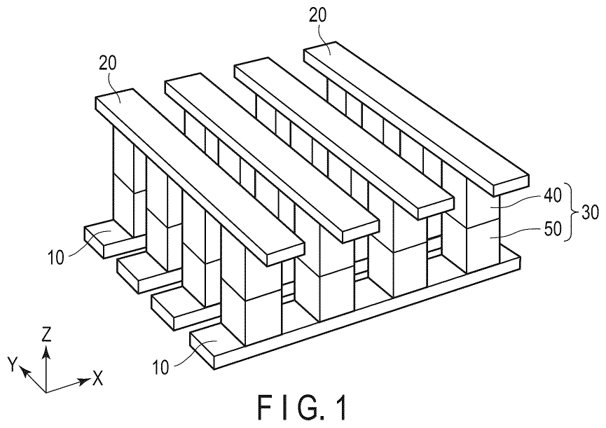

FIG. 1 is a perspective view schematically showing the configuration of a memory device according to a first embodiment.

The memory device of the embodiment is provided on a lower region (not shown) including a semiconductor substrate (not shown), and includes a plurality of lower wiring lines 10 each extending in an X-direction, a plurality of upper wiring lines 20 each extending in a Y-direction and located on the upper layer side of the lower wiring lines 10, and a plurality of memory cells 30 provided between the lower wiring lines 10 and the upper wiring lines 20.

One of each lower wiring line 10 and each upper wiring line 20 corresponds to a word line, and the other one of each lower wiring line 10 and each upper wiring line 20 corresponds to a bit line.

Each memory cell 30 includes a magnetoresistance effect element 40 which is a variable resistance memory element, and a selector 50 which is a switching element. The magnetoresistance effect element 40 and the selector 50 are connected in series between the lower wiring line 10 and the upper wiring line 20 and are stacked in a Z-direction.

It should be noted that the X-direction, the Y-direction and the Z-direction are directions which intersect each other. More specifically, the X-direction, the Y-direction and the Z-direction are orthogonal to each other.

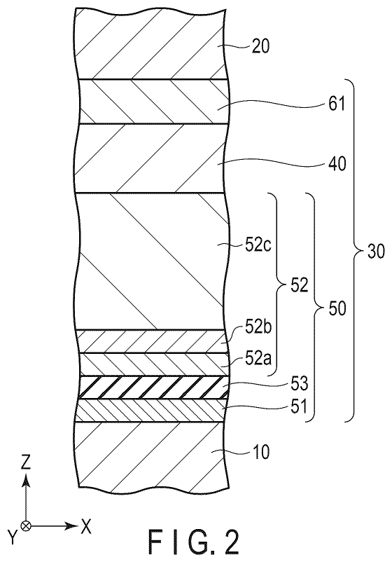

FIG. 2 is a cross-sectional view schematically showing the configuration of the memory device according to the embodiment.

As described above, the memory device of the embodiment includes the lower wiring lines 10, the upper wiring lines 20 and the memory cells 30 provided between the lower wiring lines 10 and the upper wiring lines 20.

In this embodiment, each memory cell 30 includes the magnetoresistance effect element 40 (which is also referred to as a magnetoresistance effect element body, and which is a nonvolatile variable resistance memory element. In the following explanation, the magnetoresistance effect element is adopted as the variable resistance memory element.), the selector 50 and an electrode 61 provided between the magnetoresistance effect element 40 and the upper wiring line 20. In this embodiment, the selector 50 is provided on the lower layer side of the magnetoresistance effect element 40. Although not shown in the figure, a sidewall insulating layer is provided on a side surface of the magnetoresistance effect element 40 and a side surface of the selector 50, and an interlayer insulating layer is provided in the region between adjacent memory cells 30.

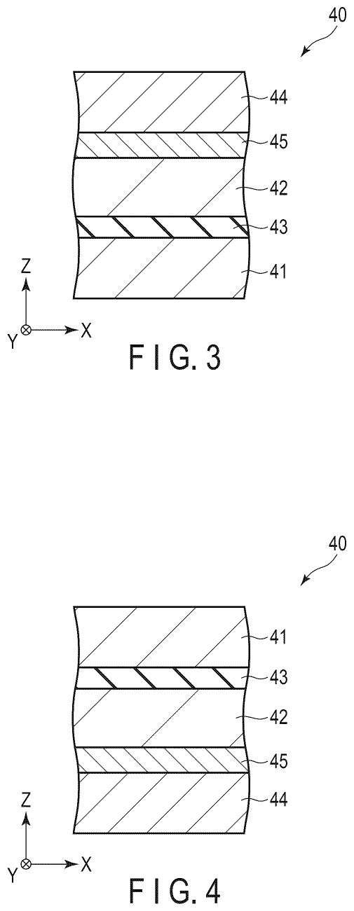

FIG. 3 is a cross-sectional view schematically showing an example of the configuration of the magnetoresistance effect element 40.

The magnetoresistance effect element 40 is a magnetic tunnel junction (MTJ) element, includes a storage layer (first magnetic layer) 41, a reference layer (second magnetic layer) 42, a tunnel barrier layer (nonmagnetic layer) 43, a shift canceling layer (third magnetic layer) 44 and an intermediate layer 45, and comprises a structure in which these layers 41 to 45 are stacked in the Z-direction.

The storage layer 41 is a ferromagnetic layer having a variable magnetization direction, and is formed of, for example, a CoFeB layer which contains cobalt (Co), iron (Fe) and boron (B). The variable magnetization direction indicates that the magnetization direction changes for a predetermined write current.

The reference layer 42 is a ferromagnetic layer having a fixed magnetization direction, and is formed of, for example, a CoFeB layer which contains cobalt (Co), iron (Fe) and boron (B). The fixed magnetization direction indicates that the magnetization direction does not change for a predetermined write current.

The tunnel barrier layer 43 is an insulating layer provided between the storage layer 41 and the reference layer 42, and is formed of, for example, an MgO layer which contains magnesium (Mg) and oxygen (O).

The shift canceling layer 44 is a ferromagnetic layer having a fixed magnetization direction which is antiparallel to the magnetization direction of the reference layer 42, and functions to cancel the magnetic field applied from the reference layer 42 to the storage layer 41. The shift canceling layer 44 is formed of, for example, a superlattice layer in which cobalt (Co) and platinum (Pt) are alternately stacked.

The intermediate layer 45 is provided between the reference layer 42 and the shift canceling layer 44 and is formed of, for example, a ruthenium (Ru) layer.

When the magnetization direction of the storage layer 41 is parallel to the magnetization direction of the reference layer 42, the magnetoresistance effect element 40 is in a low resistive state where the resistance is relatively low. When the magnetization direction of the storage layer 41 is antiparallel to the magnetization direction of the reference layer 42, the magnetoresistance effect element 40 is in a high resistive state where the resistance is relatively high. Thus, the magnetoresistance effect element 40 can store binary data based on its resistive state.

FIG. 4 is a cross-sectional view schematically showing another example of the configuration of the magnetoresistance effect element 40.

The magnetoresistance effect element 40 shown in FIG. 3 is a bottom free magnetoresistance effect element in which the storage layer 41 is located on the lower layer side of the reference layer 42. To the contrary, the magnetoresistance effect element 40 shown in FIG. 4 is a top free magnetoresistance effect element in which the storage layer 41 is located on the upper layer side of the reference layer 42. In the magnetoresistance effect element 40 shown in FIG. 4, the layers 41 to 45 are stacked in the reverse order of the magnetoresistance effect element 40 shown in FIG. 3.

In place of the magnetoresistance effect element 40 shown in FIG. 3, the magnetoresistance effect element 40 shown in FIG. 4 may be used.

When explanation returns to FIG. 2, the selector 50 includes a bottom electrode 51, a top electrode 52 provided on the upper layer side of the bottom electrode 51, and a selector material layer (switching material layer) 53 provided between the bottom electrode 51 and the top electrode 52, and comprises a structure in which these layers 51 to 53 are stacked in the Z-direction.

The bottom electrode 51 is formed of a conductive material and is provided between the selector material layer 53 and the lower wiring line 10.

The top electrode 52 is formed of a conductive material and is provided between the selector material layer 53 and the magnetoresistance effect element 40. The top electrode 52 functions as the top electrode of the selector 50 and also functions as the bottom electrode of the magnetoresistance effect element 40.

The top electrode 52 includes a first layer portion 52a, a second layer portion 52b and a third layer portion 52c, and comprises a structure in which these layers 52a, 52b and 52c are stacked in the Z-direction. Specifically, the first layer portion 52a and the second layer portion 52b are provided between the selector material layer 53 and the third layer portion 52c. The first layer portion 52a is provided between the selector material layer 53 and the second layer portion 52b. The second layer portion 52b is provided between the first layer portion 52a and the third layer portion 52c.

The first layer portion 52a is formed of a conductive material which contains carbon (C). Specifically, the first layer portion 52a is formed of a carbon (C) layer or a carbon nitride (CN) layer.

The second layer portion 52b is formed of a conductive material which contains at least one element selected from tantalum (Ta), titanium (Ti), tungsten (W), nickel (Ni), molybdenum (Mo), chromium (Cr), vanadium (V), zirconium (Zr), aluminum (Al), hafnium (Hf), indium (In), tin (Sn), ruthenium (Ru), zinc (Zn) and magnesium (Mg).

The second layer portion 52b may be formed of a conductive material which contains the at least one element described above, and at least one element selected from nitrogen (N), silicon (Si), carbon (C) and oxygen (O). For example, the conductivity of the second layer portion 52b can be assured by appropriately adjusting the proportion of these additive elements.

For example, the second layer portion 52b is formed of a layer selected from a Ta layer, TaN layer, Ti layer, TiN layer, TiC layer, W layer, WN layer, WSi layer, WSiN layer, Ni layer, Mo layer, Cr layer, V layer, CrN layer, ZrN layer, AlN layer, HfN layer, indium tin oxide (ITO) layer, RuO layer, SnO layer, AlO layer, ZnO layer and MgO layer.

The third layer portion 52c is not particularly limited, and predetermined conductive materials may be used.

The selector material layer 53 is formed of a material which contains silicon (Si), oxygen (O) and arsenic (As). Specifically, the selector material layer 53 is formed of a silicon oxide which contains arsenic (As). The selector material layer 53 may contain at least one element selected from titanium (Ti), nitrogen (N) and carbon (C) in addition to silicon (Si), oxygen (O) and arsenic (As).

For example, the selector material layer 53 is formed of a silicon oxide which contains As, a silicon oxide which contains As and Ti, a silicon oxide which contains As and N, a silicon oxide which contains As and C, a silicon oxide which contains As, Ti and N, or a silicon oxide which contains As, Ti, N and C.

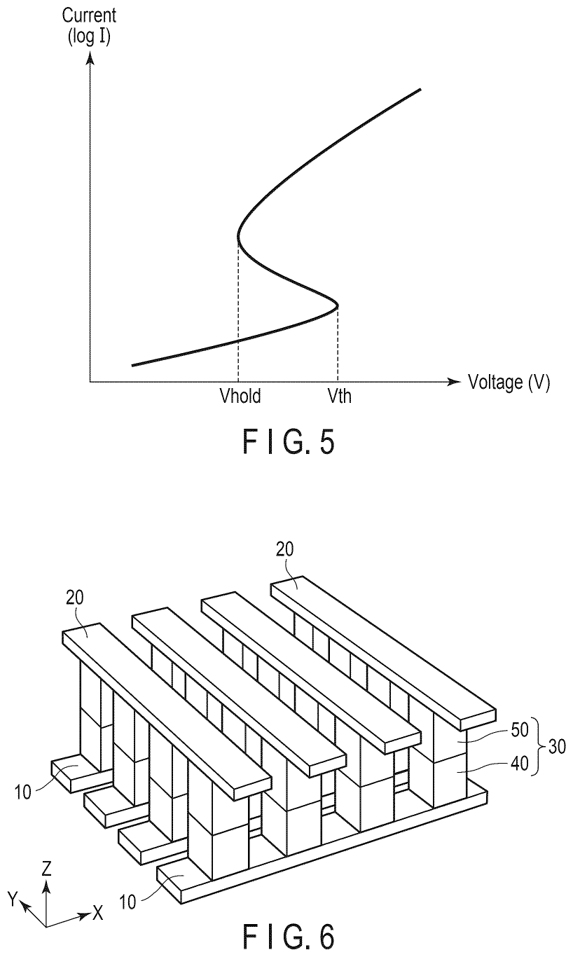

FIG. 5 is a diagram schematically showing the current-voltage characteristic of the selector 50.

The selector 50 has characteristics in which it changes from an off-state to an on-state when the voltage applied between the bottom electrode 51 and the top electrode 52 is greater than or equal to a threshold voltage Vth, and it changes from an on-state to an off-state when the voltage applied between the bottom electrode 51 and the top electrode 52 is less than or equal to a hold voltage Vhold.

Thus, when the voltage applied to the selector 50 is greater than or equal to the threshold voltage Vth by applying voltage between the lower wiring line 10 and the upper wiring line 20, the selector 50 changes from an off-state to an on-state. This enables write or read for the magnetoresistance effect element 40 which is connected to the selector 50 in series.

The electrode 61 is formed of a conductive material, is provided between the magnetoresistance effect element 40 and the upper wiring line 20 and functions as the top electrode of the magnetoresistance effect element 40.

As described above, in this embodiment, the top electrode 52 of the selector 50 includes the first layer portion 52a and the second layer portion 52b, and the first layer portion 52a is provided between the selector material layer 53 and the second layer portion 52b. By this configuration, in this embodiment, as described below, the memory device including the selector 50 having excellent characteristics can be obtained.

In the embodiment, the top electrode 52 of the selector 50 includes the first layer portion 52a formed of a conductive material which contains carbon (C). The characteristics of the selector 50 can be improved by providing the first layer portion 52a which contains carbon so as to be adjacent to the selector material layer 53.

Further, the diffusion of the carbon contained in the first layer portion 52a to the upper layer side can be prevented by providing the second layer portion 52b on the first layer portion 52a. For example, the material used for the second layer portion 52b as described above has characteristics in which the melting point is high, and has excellent stability. This configuration can effectively prevent the diffusion of the carbon contained in the first layer portion 52a. In addition, the material used for the second layer portion 52b has excellent thermal conductivity and electrical conductivity. Thus, the material is also suitable as an electrode material.

Therefore, in the embodiment, the selector 50 having excellent stability and characteristics can be obtained by providing the first layer portion 52a on the selector material layer 53 and providing the second layer portion 52b on the first layer portion 52a.

It should be noted that, in the embodiment described above, the top electrode 52 of the selector 50 includes the third layer portion 52c in addition to the first layer portion 52a and the second layer portion 52b. However, the third layer portion 52c may not be provided.

### Second Embodiment

Now, a second embodiment is explained. As the basic matters are similar to those of the first embodiment, explanations of the matters described in the first embodiment are omitted.

FIG. 6 is a perspective view schematically showing the configuration of a memory device according to the second embodiment.

In this embodiment, in a manner similar to that of the first embodiment, memory cells 30 each including a magnetoresistance effect element 40 and a selector 50 are provided between lower wiring lines 10 and upper wiring lines 20. It should be noted that, in the first embodiment, each selector 50 is provided on the lower side of the magnetoresistance effect element 40. However, in the second embodiment, each selector 50 is provided on the upper layer side of the magnetoresistance effect element 40.

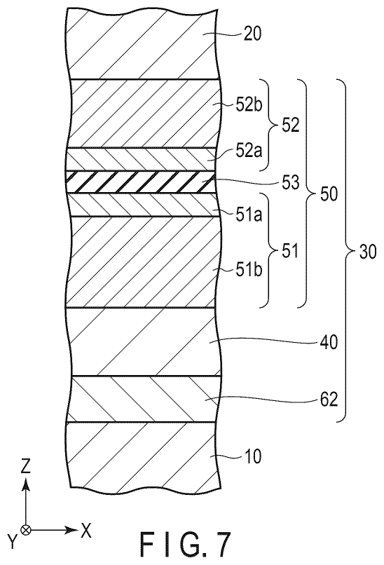

FIG. 7 is a cross-sectional view schematically showing the configuration of the memory device according to the embodiment.

In this embodiment, the memory cell 30 includes the magnetoresistance effect element 40, the selector 50 and an electrode 62 provided between the magnetoresistance effect element 40 and the lower wiring line 10.

The basic configuration of the magnetoresistance effect element 40 is similar to that of the magnetoresistance effect element 40 of the first embodiment. Therefore, the magnetoresistance effect element 40 shown in FIG. 3 or FIG. 4 may be used.

The basic configuration of the selector 50 is also similar to that of the selector 50 of the first embodiment. Specifically, the selector 50 includes a bottom electrode 51, a top electrode 52 provided on the upper layer side of the bottom electrode 51, and a selector material layer 53 provided between the bottom electrode 51 and the top electrode 52, and comprises a structure in which these layers 51 to 53 are stacked in a Z-direction.

The bottom electrode 51 is formed of a conductive material and is provided between the selector material layer 53 and the magnetoresistance effect element 40. The bottom electrode 51 functions as the bottom electrode of the selector 50 and also functions as the top electrode of the magnetoresistance effect element 40.

The bottom electrode 51 includes a first layer portion 51a and a second layer portion 51b, and comprises a structure in which these layers 51a and 51b are stacked in the Z-direction. Specifically, the first layer portion 51a is provided between the selector material layer 53 and the second layer portion 51b. For example, for the first layer portion 51a, a conductive material which is similar to that of the first layer portion 52a of the top electrode 52 of the first embodiment may be used. For the second layer portion 51b, a conductive material which is similar to that of the second layer portion 52b of the top electrode 52 of the first embodiment may be used. However, in this embodiment, the material of the first layer portion 51a of the bottom electrode 51 or the material of the second layer portion 51b is not particularly limited.

The top electrode 52 is formed of a conductive material and is provided between the selector material layer 53 and the upper wiring line 20.

The top electrode 52 includes a first layer portion 52a and a second layer portion 52b, and comprises a structure in which these layers 52a and 52b are stacked in the Z-direction. Specifically, the first layer portion 52a is provided between the selector material layer 53 and the second layer portion 52b. For the first layer portion 52a, a conductive material which is similar to that of the first layer portion 52a of the top electrode 52 of the first embodiment may be used. For the second layer portion 52b, a conductive material which is similar to that of the second layer portion 52b of the top electrode 52 of the first embodiment may be used.

The selector material layer 53 is provided between the bottom electrode 51 and the top electrode 52. For the selector material layer 53, a material similar to that of the selector material layer 53 of the first embodiment may be used.

The electrode 62 is formed of a conductive material, is provided between the magnetoresistance effect element 40 and the lower wiring line 10 and functions as the bottom electrode of the magnetoresistance effect element 40.

As described above, in this embodiment, in a manner similar to that of the first embodiment, the top electrode 52 of the selector 50 includes the first and second layer portions 52a and 52b formed of materials similar to those of the first embodiment, and the first layer portion 52a is provided between the selector material layer 53 and the second layer portion 52b. Therefore, in this embodiment, in a manner similar to that of the first embodiment, the diffusion of the carbon contained in the first layer portion 52a to the upper layer side can be prevented, and the selector 50 having excellent stability and characteristics can be obtained.

In the first and second embodiments described above, a magnetoresistance effect element is used as a variable resistance memory element. However, other variable resistance memory elements may be used.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A memory device comprising:
a lower wiring line extending in a first direction;
an upper wiring line extending in a second direction intersecting the first direction; and
a memory cell provided between the lower wiring line and the upper wiring line and including a variable resistance memory element and a switching element stacked in a third direction intersecting the first direction and the second direction,
wherein
the switching element includes a structure in which a bottom electrode, a top electrode and a switching material layer provided between the bottom electrode and the top electrode are stacked in the third direction,
the top electrode includes a first layer portion and a second layer portion stacked in the third direction, and includes a structure in which the first layer portion is provided between the switching material layer and the second layer portion,
the switching material layer is formed of a material containing silicon (Si), oxygen (O) and arsenic (As),
the first layer portion is formed of a conductive material containing carbon (C), and
the second layer portion is formed of a conductive material containing at least one element selected from tantalum (Ta), titanium (Ti), tungsten (W), nickel (Ni), molybdenum (Mo), chromium (Cr), vanadium (V), zirconium (Zr), aluminum (Al), hafnium (Hf), indium (In), tin (Sn), ruthenium (Ru), zinc (Zn) and magnesium (Mg).

2. The memory device of claim 1, wherein
the switching element is provided on a lower layer side of the variable resistance memory element, and
the top electrode is provided between the switching material layer and the variable resistance memory element.

3. The memory device of claim 1, wherein
the switching element is provided on an upper layer side of the variable resistance memory element, and
the top electrode is provided between the switching material layer and the upper wiring line.

4. The memory device of claim 1, wherein
the first layer portion is formed of a carbon (C) layer or a carbon nitride (CN) layer.

5. The memory device of claim 1, wherein
the second layer portion further contains at least one element selected from nitrogen (N), silicon (Si), carbon (C) and oxygen (O).

6. The memory device of claim 1, wherein
the second layer portion is formed of a layer selected from a Ta layer, TaN layer, Ti layer, TiN layer, TiC layer, W layer, WN layer, WSi layer, WSiN layer, Ni layer, Mo layer, Cr layer, V layer, CrN layer, ZrN layer, AlN layer, HfN layer, indium tin oxide (ITO) layer, RuO layer, SnO layer, AlO layer, ZnO layer and MgO layer.

7. The memory device of claim 1, wherein
the switching material layer further contains at least one element selected from titanium (Ti), nitrogen (N) and carbon (C).

8. The memory device of claim 1, wherein
the top electrode further includes a third layer portion, and
the second layer portion is provided between the first layer portion and the third layer portion.

9. The memory device of claim 1, wherein
the variable resistance memory element is a magnetoresistance effect element.

10. The memory device of claim 1, wherein
the switching element has characteristics of changing from an off-state to an on-state when voltage applied between the bottom electrode and the top electrode is greater than or equal to a threshold voltage.

11. The memory device of claim 10, wherein
when the switching element is in an on-state by applying voltage between the lower wiring line and the upper wiring line, write or read for the variable resistance memory element is enabled.
